(19) United States
(12) Patent Application Publication
(10) Pub. No.: US 2011/0053355 A1
(43) Pub. Date: Mar. 3, 2011

(54) Plasma apparatus and method of fabricating nano-crystalline silicon thin film

(75) Inventors: Jeff Tsai, Taipei City (TW); Tsung-Ying Lin, Hualien County (TW); Zi-Jie Liao, Taipei City (TW); Jia-Ling Peng, Taoyuan County (TW); Chia-Lin Liu, Taichung County (TW); Chi-Neng Mo, Taoyuan County (TW)

(73) Assignee: Chunghwa Picture Tubes, LTD., Taoyuan (TW)

(21) Appl. No.: 12/589,282

(22) Filed: Oct. 20, 2009

(30) Foreign Application Priority Data
Sep. 3, 2009 (TW) 98129732

(51) Int. Cl. H01L 21/20

(52) U.S. Cl. 438/486; 118/723 E; 257/E21.133

(57) ABSTRACT

A plasma apparatus having a chamber, a set of arc electrodes and a substrate holder is provided. The set of arc electrodes disposed within the chamber has an anode and a cathode, wherein an arc forming space is formed between the anode and the cathode. The anode and the cathode respectively have a crystallized silicon target. The crystallized silicon target of the anode is disposed on an end facing to that of the cathode, wherein the resistance of the crystallized silicon targets is smaller than 0.01 Ω·cm. The substrate holder is disposed within the chamber and has a carrying surface, wherein the carrying surface is face to the arc forming space. Besides, a method of fabricating nano-crystalline silicon thin film is also provided. By using the plasma apparatus, a nano-crystalline silicon thin film with high quality is formed.

### CROSS-REFERENCE TO RELATED APPLICATION

This application claims the priority benefit of Taiwan application serial no. 98129732, filed on Sep. 3, 2009. The entirety of the above-mentioned patent application is hereby incorporated by reference herein and made a part of this specification.

### BACKGROUND OF THE INVENTION

1. Field of the Invention

The present invention relates to a semiconductor apparatus and a method of fabricating a thin film. More particularly, the present invention relates to a plasma apparatus and a method of fabricating a nano-crystalline silicon thin film.

2. Description of Related Art

Plasma is the most widely adopted process for cleaning, coating, sputtering in the semiconductor process, and also used in a plasma chemical vapor deposition (plasma CVD) process, an ion implantation process, a vacuum arc process, a plasma immersion ion implantation (PIII) or etching process.

In conventional technology, plasma is usually used for forming thin films within the semiconductor process, and the products made from the formed thin films may be applied to us as thin films of the solar cells, and various semiconductor devices, such as thin-film transistors (TFT) array, of the liquid crystal display.

FIG. 1 is a schematic view of plasma apparatus according to U.S. Pat. No. 5,952,061. Referring to FIG. 1, plasma apparatus includes a chamber 1, a substrate holder 10, an electrode plate 12, a crucible 3, and a gas pipe 16. The substrate 11 is disposed on the substrate holder 9. The silicon alloy 8 filled in the crucible 3 can function as silicon source. When a voltage difference is applied between the electrode plate 12 and the crucible 3 by a DC voltage source, a neutral gas, such as argon, helium, neon, and xenon, passing from the gas pipe 16 is used as a medium for producing plasma. The applied DC current is between 100 amperes and 200 amperes. At this time, the silicon alloy 8 in the crucible 3 is heated, and thus silicon vapor is produced and distributed in the chamber 1. Afterwards, silicon atoms of the silicon vapor dispersed in the chamber 1 are gradually deposited on the substrate 11. As shown in FIG. 1, the substrate holder 9 has a heater 10, and a silicon thin film is growth through a heating process by the heater 10 on the substrate 11.

However, in the foregoing plasma apparatus disclosed by U.S. Pat. No. 5,952,061, it needs to heat the substrate to a temperature higher than 300° C. for growing the silicon thin film. Therefore, the silicon thin film may not be grown regarding to those substrates vulnerable to heat, such as flexible substrates. As a results, the various semiconductors thin film, such as thin-film transistors (TFT) array, used in the solar cells, and the liquid crystal display may not be successfully produced due to limitation of process.

### SUMMARY OF THE INVENTION

An embodiment of the present invention provides a plasma apparatus to produce a thin film having an excellent photoconductivity characteristic without applying an additional doping process.

An embodiment of the present invention provides a method of fabricating a nano-crystalline silicon thin film, which has an excellent photoconductivity characteristic.

An embodiment of the present invention provides a plasma apparatus. The plasma includes a chamber, an arc electrode set, and a substrate holder. The arc electrode set is disposed in the chamber, and the arc electrode includes an anode and a cathode, wherein an arc discharging space is formed between the anode and the cathode. The opposite ends of the cathode and the anode opposite to each other respectively has an crystallized silicon target, wherein the resistance of the crystallized silicon targets is smaller than 0.01 Ω·cm. The substrate holder is disposed within the chamber. The substrate holder has a carrier surface facing to the arc discharging space.

In an embodiment of the present invention, each of the above-mentioned crystallized silicon targets has a single crystal structure of silicon, and each of the single crystal structure of silicon grains has dopants with high dopant concentration, wherein the dopant concentration of the dopants in each of the single crystal structure of silicon grains is substantially from 10¹⁹ to 10²⁰ atom/cm². More specifically, a material of the above-mentioned dopants with high dopant concentration in the crystallized silicon targets can be selected from the III-group elements, and the crystallized silicon targets constitute P-type semiconductor targets. Alternatively, a material of the dopants can be also selected from the V-group elements, and thus the crystallized silicon targets constitute N-type semiconductor targets. Certainly, a material of the above-mentioned dopants with high dopant concentration in the crystallized silicon targets can also be selected from the III-group elements and the V-group elements, and thus the crystallized silicon targets constitute intrinsic semiconductor targets.

In an embodiment of the present invention, a resistance of the above-mentioned crystallized silicon targets is greater than 0.005 Ω/cm.

In an embodiment of the present invention, the above-mentioned plasma apparatus can further includes a movable mechanism, wherein the movable mechanism is connected to the arc electrode set. A relative displacement is generated between the anode and the cathode by the movable mechanism.

In an embodiment of the present invention, the above-mentioned plasma can further include a substrate, wherein the substrate is disposed on the carrier surface of the substrate holder. The substrate holder may further include a cooling system, wherein the cooling system is buried inside the carrier surface, so as to force cool the heated substrate during process. Moreover, the cooling system may include a cooling pipe and a coolant, wherein the cooling pipe passes through a trench buried inside the substrate holder, and the coolant flows and circulates in the cooling pipe. At this moment, the above-mentioned carrier surface is forced to cool to a temperature substantially smaller than 0° C. by the cooling system during the process. For example, the above-mentioned coolant includes water or liquid nitrogen.

According to an embodiment of the present invention, the above-mentioned substrate is a flexible substrate.

According to an embodiment of the present invention, a surface of the above-mentioned substrate to be deposited may be a flat surface, a spherical surface or a mirror surface.

According to an embodiment of the present invention, the above-mentioned plasma apparatus may further include a continuous feeding system, wherein the continuous feeding system is connected to the substrate, and the substrate is carried to be disposed on the substrate holder through the continuous feeding system.

According to an embodiment of the present invention, the above-mentioned plasma apparatus may further include a gas pipe, wherein the gas pipe is disposed on the sidewall of the chamber, and the dopant gas passing through the gas pipe includes diborane or phosphine.

Another embodiment of the present invention provides a method of fabricating a nano-crystalline silicon thin film, which is suitable of using the above-mentioned plasma apparatus, and the method of fabricating a nano-crystalline silicon thin film includes the following steps. First, a substrate is provided to dispose on a carrier surface of the substrate holder. Next, a pressure of the gas within the chamber is adjusted to an operation pressure. Then, a voltage is input so as to form a voltage difference between the anode and the cathode. Thereafter, the distance between the anode and the cathode is shorten, so as to form a stable arc plasma between the anode and the cathode. Next, the crystallized silicon target of the anode and the crystallized silicon target of the cathode form a plurality of silicon crystalline grains and silicon atoms by the stable arc plasma. Afterward, a plurality of silicon crystalline grains and silicon atoms deposit to the substrate to form a nano-crystalline silicon thin film.

According to an embodiment of the present invention, the above-mentioned silicon crystalline grains and silicon atoms formed by the stable arc plasma are in a status of high temperature. Meanwhile, the above-mentioned substrate holder may further include a cooling system, wherein the cooling system is buried inside the carrier surface. Before performing the step of forming the silicon crystalline grains and silicon atoms through the stable arc plasma, a coolant passes through the cooling system to force the heated substrate during process to cool, so that the high-temperature silicon crystalline grains and silicon atoms are quenched and deposited to the substrate.

According to an embodiment of the present invention, the above-mentioned nano-crystalline silicon thin film may include a continuous phase of amorphous silicon layer, and a plurality of single crystal of silicon grains dispersed within the amorphous silicon layer.

According to an embodiment of the present invention, a size of each of the above-mentioned single crystal of silicon grains is substantially from 100 nanometers to 5 micrometers.

According to an embodiment of the present invention, the above-mentioned substrate may be a flexible substrate, wherein the substrate is continuously fed, such that a nano-crystalline silicon thin film is continuously deposited on the substrate fed continuously.

Based on the above, by utilizing an arc electrode set having crystallized silicon targets, the plasma apparatus of the present invention is capable of producing high quality nano-crystalline silicon thin films by a simple process. In one embodiment, a cooling system is further installed on the substrate holder, so as to force the heated substrate during process to cool. As such, nano-crystalline silicon thin films can be formed on the substrates which are vulnerable to heat.

To make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional plasma apparatus.

FIG. 2 is a cross-sectional view of a plasma apparatus of one embodiment of the present invention.

FIG. 3 is an enlarged partial schematic view of moving tracks of the arc electrode shown in FIG. 2.

FIG. 4 is a schematic view of a state when an arc discharge is produced in one embodiment of the present invention.

FIG. 5 is an enlarged partial schematic view of feeding method of the substrate according to one embodiment of the present invention.

FIG. 6 is schematic view showing a method of fabricating a nano-crystalline silicon thin film according to one embodiment of the present invention.

FIG. 7 is a Raman spectrum of a nano-crystalline silicon thin film fabricating by a plasma apparatus of one embodiment of the present invention.

FIG. 8 is schematic view of Transmission Electron Microscope of a nano-crystalline silicon thin film fabricating by a plasma apparatus of one embodiment of the present invention.

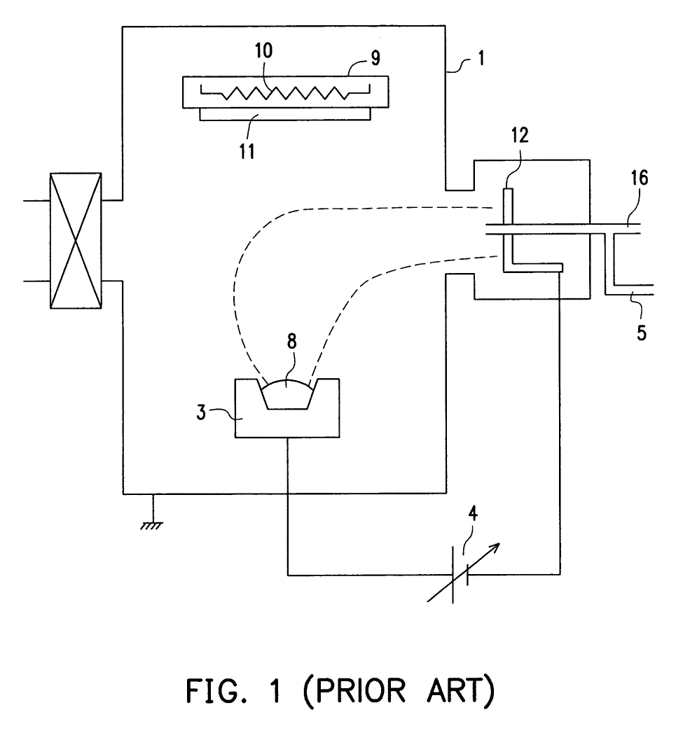

### DESCRIPTION OF EMBODIMENTS

A plasma apparatus of an embodiment of the present invention mainly provides a novel and simple fabricating method to directly form a nano-crystalline silicon thin film having excellent photoconductivity characteristics by installing crystallized silicon targets respectively on the opposite sides of an arc electrode set. When an appropriate voltage is applied between a cathode and an anode of the arc electrode set, silicon crystalline grains of the crystallized silicon targets obtain a sufficient energy through an arc, so that the silicon crystalline grains and silicon atoms are vapored to gas phase. Meanwhile, the silicon crystalline grains and silicon atoms in gas phrase and formed in the solid state are well mixed, and thus forming a nano-crystalline silicon thin film having excellent photoconductivity characteristics with highly dispersing silicon crystalline grains therein.

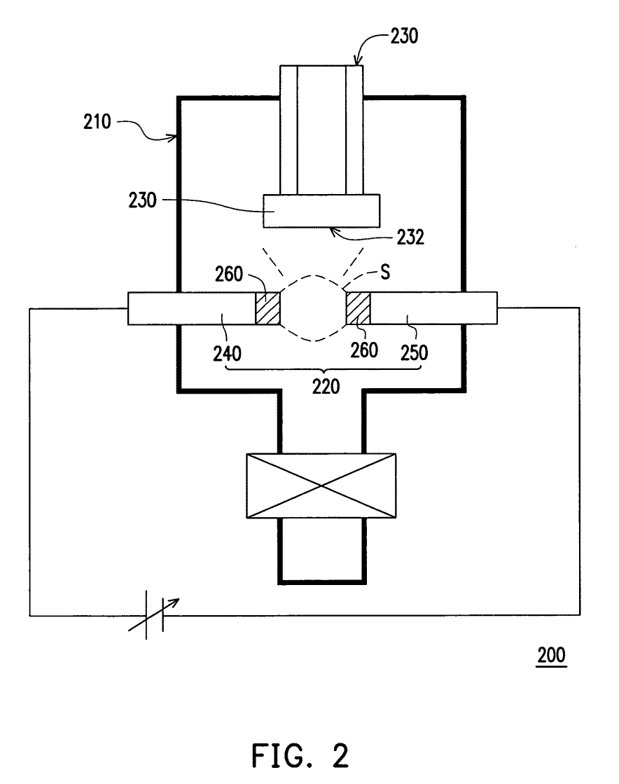

FIG. 2 is a cross-sectional view of a plasma apparatus of one embodiment of the present invention. Referring to FIG. 2, the plasma apparatus 200 includes a chamber 210, an arc electrode set 220, and a substrate holder 230. The arc electrode set 220 is disposed in the chamber 210, and the arc electrode 220 includes an anode 240 and a cathode 250, wherein an arc discharging space S is formed between the anode 250 and the cathode 240. The opposite ends of the cathode 250 and the anode 240 opposite to each other respectively has an crystallized silicon target 260, wherein the resistance of the crystallized silicon targets 260 is smaller than 0.01 Ω·cm. The substrate holder 230 is disposed within the chamber 210. The substrate holder 230 has a carrier subsurface 232 facing to the arc discharging space S. By utilizing the crystallized silicon targets 260 between the cathode 250 and the anode 240 thereof can fabricate a semiconductor thin film with excellent photoconductivity characteristics.

More specifically, as shown in FIG. 2, the crystallized silicon targets 260 are respectively on opposite sides of the cathode 250 and the anode 240 opposite to each other. In this present embodiments, the crystallized silicon targets 260 has a single crystal structure of silicon, by doping an appropriate concentration dopants to a single crystal structure of silicon to adjust the structure of the crystallized silicon targets 260 and the resistance thereof. In other words, the resistance can be reduced by increasing the dopant concentration of the dopants. Moreover, increasing the dopant concentration of dopants is conducive to produce an arc discharge between the cathode 250 and the anode 240. That is to say, when the resistance of the crystallized silicon targets 260 is smaller than 0.01 Ω·cm, the arc discharge can be produced fully within an appropriate voltage range and within an appropriate electrode distance between the cathode 250 and the anode 240. On the other hand, the upper limit of the dopant concentration in the crystallized silicon targets 260 has no particular restrictions. However, considering for reducing damage degrees of the crystallized silicon targets 260 induced by the dopants, the upper limit of the dopant concentration of dopants is preferred to not smaller than or equal to 0.005 Ω/cm, that is, when the resistance of the crystallized silicon targets 260 is greater than 0.005 Ω/cm, the crystallinity of the crystallized silicon targets 260 can be sufficiently obtained. In other words, each of the crystallized silicon targets 260 has a single crystal structure of silicon, for example, and each of the single crystal structure of silicon has dopants therein with high dopant concentration. In this embodiment, the dopant concentration of the dopants in each of the single crystal structure of silicon grains substantially ranges from 10¹⁹ to 10²⁰ atom/cm².

It should be mentioned that designers may choose an appropriate material as the dopants according to a product requirements of semiconductor thin films to be formed. For example, a product requirements for forming a structure of the semiconductor thin films may be P-type semiconductor, N-type semiconductor or a structure having a P-N diode. For instance, a material of the dopant can be also selected from the -group elements, and thus the crystallized silicon targets 260 constitute N-type semiconductor targets. Alternatively, a material of the dopants can be also selected from the V-group elements, and thus the crystallized silicon targets 260 constitute N-type semiconductor targets. Certainly, a material of the dopants can be also selected from the III-group elements and the V-group elements simultaneously, and thus the crystallized silicon targets constitute intrinsic semiconductor targets.

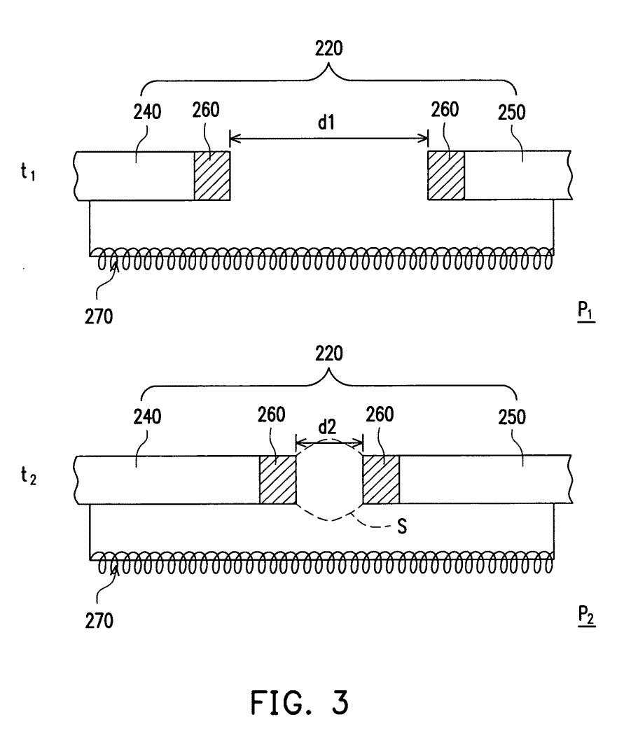

FIG. 3 is an enlarged partial schematic view of moving tracks of the arc electrode shown in FIG. 2. Referring to FIG. 3, in a practical operation, the method of forming the arc discharge may connect externally to an movable mechanism 270, wherein the movable mechanism 270 is connected to the arc electrode set 220, and disposed parallel to the cathode 250 and the anode 240. The movable mechanism 270 is such as a linear stepping motor. A relative displacement is generated between the anode 240 and the cathode 250 by the movable mechanism 270. For example, a movement of the anode 240 can approach the cathode 250 with time, and the relative displacement may function as uniform motion, uniform acceleration, uniformly retarded motion, or operation according to a predefined function. In practice, after applying a DC voltage between the anode 240 and the cathode 250, a distance between the anode 240 and the cathode 250 is gradually shortened by utilizing the movable mechanism 270 until an arc discharge is produced between the anode 240 and the cathode 250. As shown in FIG. 3, at the first timing t₁, the distance between the anode 240 and the cathode 250 is defined as d1. Then, at the first timing t₂, the distance between the approaching anode 240 and the cathode 250 is shortened to d2. At this timing, an arc discharge is produced in the arc discharge space S between the anode 240 and the cathode 250. Therefore, the moving tracks of the anode 240 and the cathode 250 is like the instantaneous position P₁ and the instantaneous position P₂ as shown in FIG. 3.

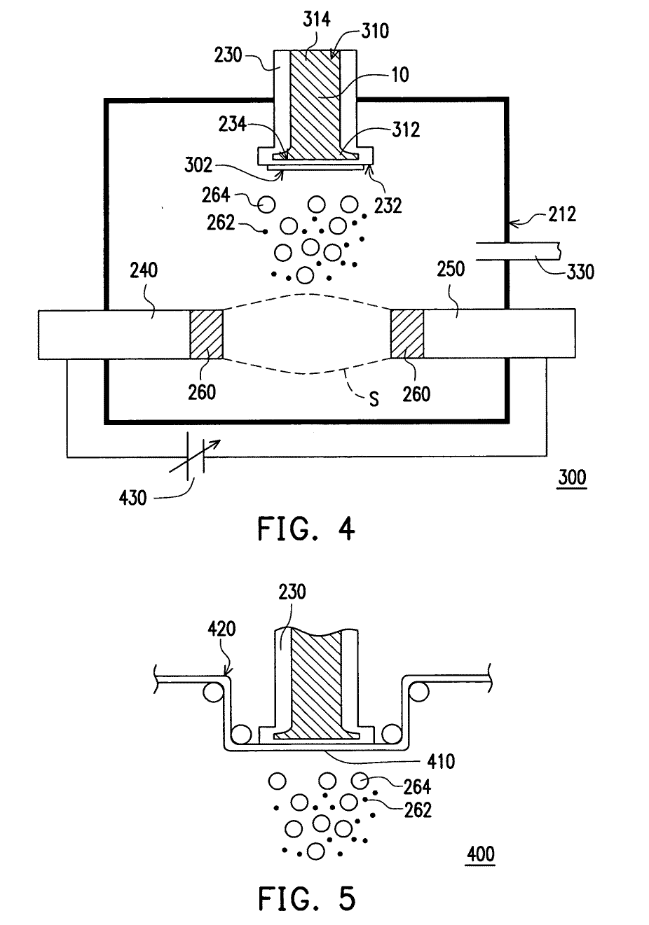

FIG. 4 is a schematic view of a state when an arc discharge is produced in one embodiment of the present invention. Referring to FIG. 4, in the plasma apparatus 300, when the arc discharge is produced, the silicon atoms 262 and the silicon crystalline grains 264 in solid state of the crystallized silicon targets 260 are transform to become the silicon atoms 262 and the silicon crystalline grains 264 in gas state through the heat produced from the instantaneous arc, so as to produce silicon source plasma within the arc discharge space S. Afterward, those silicon atoms 262 and the silicon crystalline grains 264 in gas state diffuse from the arc discharge space where the silicon source plasma is in a high concentration according to concentration gradient difference, and then deposit to the substrate to form a nano-crystalline silicon thin film. It should be mentioned that the inventor further discovers that, by producing the silicon atoms 262 and the silicon crystalline grains 264 in the same phase, the gas concentration of the silicon atoms 262 and the silicon crystalline grains 264 in gas state existed in the arc discharge space is much higher than that of silicon atoms 262 and the silicon crystalline grains 264 in gas state existed in other regions of the chamber. As a result, those silicon atoms 262 and silicon crystalline grains 264 in the same phase deposited from the arc discharge space S to the substrate would cause a certain flow rate, so that those silicon atoms 262 and silicon crystalline grains 264 generate a so-called solar wind phenomenon in the chamber 210. Generally speaking, the so-called solar wind means airstreams produced from high-speed charged particles in chamber. As such, the plasma apparatus 300 of the present invention is no need to add additional reactive gas for producing plasma and generating silicon crystalline grains 264, and thus compared with the prior art, the present invention is much simpler.

Furthermore, designers may adjust the crystalline size of the silicon crystalline grains within the nano-crystalline silicon thin film and the dispersing degree of the silicon crystalline grains spread in the nano-crystalline silicon thin film according to a desired photoconductivity characteristic of the product, such as the wavelength range of an absorb light. Specifically, the design size of the silicon crystalline grains 264 can be further controlled by adjusting the arc discharge energy, the background pressure of the chamber 210, and a distance from the substrate to the center of the arc, etc.

Referring to FIG. 4, in this embodiment, the substrate 302 is carried on the carrier surface 232 of the substrate holder 230 in practice process. Moreover, a cooling system 310 can be further installed in the substrate holder 230, wherein the cooling system 310 is buried inside the carrier surface 232 to force the heated substrate during process to cool. The cooling system 310 is mainly constituted by cooling pipe 312 and a coolant 314, for example. In detail, as shown in FIG. 4, the substrate holder 230 has a trench 234 inside, and the cooling pipe 312 passes through the trench 234 buried inside the substrate holder 230. Besides, the coolant 314 flows and circulates in the cooling pipe 312, so as to take the heat generated during the process away from the substrate 302. Regarding to the coolant 314 of the cooling system 310, the type of the coolant 314 has no particular restrictions, which can be chosen according to the different heat resistance of the substrate 302.

As shown in FIG. 4, the process temperature of the substrate 302 disposed on the carrier surface 232 can be accurately controlled by using the cooling system 310 buried in the carrier surface 232. As a result, the substrate for depositing the nano-crystalline silicon thin film can be selected from a plastic substrate 302 having flexible characteristic, such as flexible substrate, etc. Therefore, a nano-crystalline silicon thin film having a structure of P type semiconductor, N type semiconductor, or P-N diode can be fabricated on a flexible substrate by the foregoing plasma apparatus 300. Specifically, when water is used as the coolant 314, the carrier surface 232 may force the cooling system 310 to cool during process, so that the temperature of the carrier surface 232 may be kept in normal atmospheric temperature or within a range substantial greater than or equal to 0° C. Of course, when liquid nitrogen is used as the coolant 314, the carrier surface 232 may force to cool during process through the cooling system 310, so that the temperature of the carrier surface 232 may be kept within a range substantial smaller than 0° C., such as −10° C. or 77K.

Consequently, after the silicon atoms 262 in the gas state depositing on the substrate 302, a continuous thin film of amorphous silicon is thus formed. Meanwhile, the silicon crystalline grains 264 in the gas state deposit on the substrate 302 and thus disperse within the amorphous silicon layer of continuous phase, so as to form a nano-crystalline silicon thin film comprising a continuous phase of amorphous silicon layer, and a dispersing phrase of a plurality of micro crystalline structure of silicon grains dispersed therein. In the present embodiment, the size of the single crystal of silicon grains 264 ranges substantially from 100 nanometers to 5 micrometers. A detailed description of the structure of the nano-crystalline silicon thin film is described as follow.

Referring to FIG. 4, in some special application, the plasma apparatus 300 of the present invention may further include a gas pipe 330, wherein the gas pipe 330 is disposed on the sidewall 212 of the chamber 210. Herein, a dopant gas passing through the gas pipe 330 may be a compound containing third group elements, such as diborane, or containing fifth group elements, such as phosphine. Accordingly, users may further control the dopant concentration or species of dopants within the nano-crystalline silicon thin film by adjusting the flow rate and the species of the passing gas. More specifically, in the practice application, users may fabricate a continuous nano-crystalline silicon thin film having both P type semiconductor structure and N type semiconductor structure therein during a sequential processing by adjusting the species of the passing gas without exchanging the crystallized silicon targets.

Besides, in practice, the substrate may be a glass substrate or a plastic substrate like flexible substrate. FIG. 5 is an enlarged partial schematic view of feeding method of the substrate according to one embodiment of the present invention. In order to explain the present embodiment, only a substrate holder, a substrate and a continuous feeding system are illustrated in the FIG. 5, and some of the possible existing devices are omitted in the drawing. In practice, in consideration of mass production, the plasma apparatus 400 may further include a continuous feeding system 420, which is connected to the substrate 410. The substrate 410 is carrier to be disposed on the substrate holder 230 through the continuous feeding system 420. Accordingly, the nano-crystalline silicon thin film can be continuously deposited on the substrate 410, so as to realize the possibility of fabricating a large-area electrical-optical product, and increase the application. Moreover, the scope of the present invention is not restricted to any shape of surface to be deposited of the substrate. For example, a surface to be deposited of the above-mentioned substrate may be a flat surface, a spherical surface or a mirror surface.

In order to illustrate the method of fabricating a nano-crystalline silicon thin film by utilizing the aforesaid plasma apparatus in the present invention, the plasma apparatus 300 as shown in FIG. 4 is taken as an example to describe the following embodiments, but the embodiments in the follows are not limit the present invention.

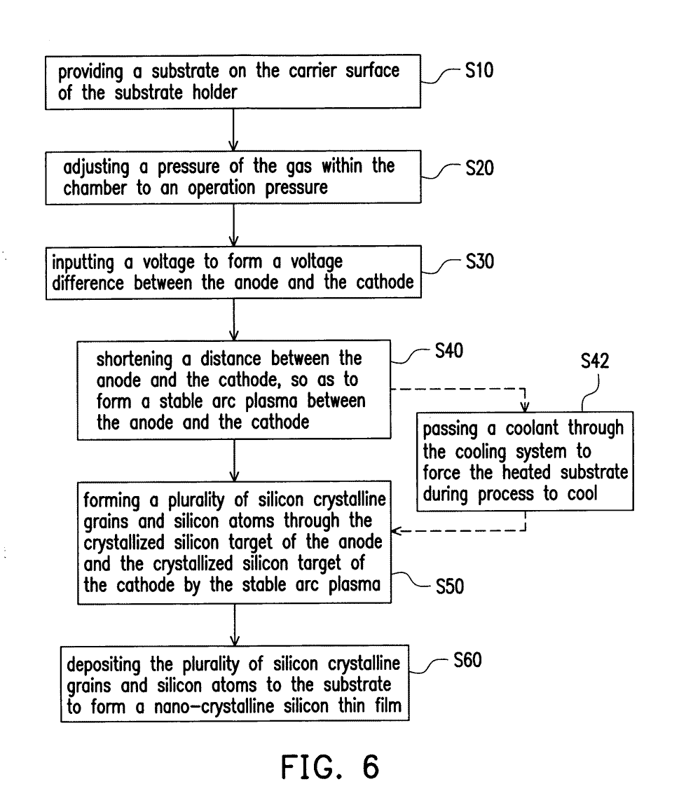

FIG. 6 is schematic view showing a method of fabricating a nano-crystalline silicon thin film according to one embodiment of the present invention. The method of fabricating a nano-crystalline silicon thin film includes the following steps. Referring to FIG. 2 and FIG. 6, in the step S10, a substrate 302 is first provided on the carrier surface 232 of the substrate holder 230. Then, in the step S20, a pressure of the gas within the chamber 210 is adjusted to an operation pressure.

Afterward, in the step S30, a voltage is applied so as to form a voltage difference V between the anode 240 and the cathode 250. Thereafter, in the step S40, the distance between the anode 240 and the cathode 250 is shorten, so as to form a stable arc plasma between the anode 240 and the cathode 250. It should be noted that the silicon crystalline grains 264 and silicon atoms 262 formed by the stable arc plasma in this step are in a status of high temperature. Next, in the step S50, the crystallized silicon target 260 of the anode 240 and the crystallized silicon target 260 of the cathode 250 form a plurality of silicon crystalline grains 264 and silicon atoms 262 by the stable arc plasma.

Specially, a step S42 may further be performed before performing the step of forming the silicon crystalline grains 264 and silicon atoms 262. Referring to step S42, the substrate holder 230 may further include a cooling system 310 buried inside the carrier surface 232. A coolant 314 passes through the cooling system 310 to force the heated substrate 302 during process to cool, so that the high-temperature silicon crystalline grains 264 and silicon atoms 262 are quenched and deposited to the substrate 302.

Afterward, in the step S60, the plurality of silicon crystalline grains 264 and silicon atoms 262 deposit to the substrate 302 and thus form a nano-crystalline silicon thin film. In the present embodiment, the nano-crystalline silicon thin film includes a continuous phase of amorphous silicon layer, and a plurality of single crystalline grains 264 dispersed within the amorphous silicon layer, wherein the size of each of the single crystalline grains 264 is substantially from 100 nanometers to 5 micrometers Furthermore, as mentioned above, the substrate 302 may be flexible substrate and is continuously fed, such that a nano-crystalline silicon thin film is continuously deposited on the continuous-fed substrate 302.

In order to illustrate the present invention, an represent embodiment according to the aforesaid plasma apparatus is taken as an example to illustrate the present invention, but the embodiments in the follows are not limit the present invention.

### Embodiment

In the following embodiment, the plasma apparatus 300 as shown in FIG. 4 is utilized, and the method of fabricating a nano-crystalline silicon thin film is according to the FIG. 6. Referring to FIG. 4 and FIG. 6 for illustrating the following embodiments.

First, a flexible substrate 302 is input to the chamber 210. Next, the pressure of the chamber 210 is extracted to an operation pressure 8×10⁻⁶˜5×10⁻⁵ torr which is deemed a substantial vacuum state by using a vacuum pump. Next, a coolant 314, such as liquid nitrogen, passes through the cooling pipe 312 of the substrate holder 230, so as to keep the substrate 302 in a low temperature environment. In this present embodiment, the temperature of the substrate 302 is controlled to 77K, for example. Then, a DC voltage power 430 is externally connected to the anode 240 and the cathode 250 of the arc electrode set 220, and an electric current substantial ranging from 20 amperes to 30 amperes is applied to the anode 240 and the cathode 250.

Then, the anode 240 and the cathode 250 are gradually approached to each other by utilizing a linear stepping motor and the a distance therebetween is shortened until an arc discharge is produced in the arc discharge space S between the anode 240 and the cathode 250. Accordingly, the silicon atoms 262 and the silicon crystalline grains 264 of the crystallized silicon targets 260 are vapored through obtaining the heat producing by the arc discharge, so as to generate a silicon source plasma and thus deposit to the substrate 302.

The crystalline ratio of the nano-crystalline silicon thin film fabricated by the above parameters is about 40% to 70%. The structure of the nano-crystalline silicon thin film can be adjusted according to the product requirements, such as P-type semiconductor, N-type semiconductor or a P-N diode structure. Therefore, considering the utility in industry, the nano-crystalline silicon thin film fabricated by the plasma apparatus 300 of one embodiment of the present invention has certain potential to apply to thin film transistors fields and solar cells fields. Compare with an amorphous silicon thin film, the nano-crystalline silicon thin film has better stability and higher electron mobility after chronically irradiated by a light, and thus has an excellent photoconductivity characteristic. Specially, in one embodiment, a nano-crystalline silicon thin film having micro crystalline structures can be directly formed on the low-temperature flexible substrate, such as plastic substrate 302, by the plasma apparatus 300. Accordingly, the application of the nano-crystalline silicon thin film is highly developed and spread to flexible displays and flexible solar cells.

In addition, compare with the prior art, when using the plasma apparatus 300 of one embodiment in the present invention, a nano-crystalline silicon thin film having micro crystalline structures can be directly formed on the substrate 302 by directly using arc discharge to vapor the silicon atoms 262 and the silicon crystalline grains 264 of the crystallized silicon targets 260, rather than taking an additional process to produce crystallization of the silicon atoms 262 deposited to the substrate 302. Besides, since the source of the silicon atoms 262 and the silicon crystalline grains 264 within the thin film are generated from the crystallized silicon targets 260, compare to the prior art that is need to inject an additional medium gas to function as the silicon atoms source within the thin film, the plasma apparatus 300 of one embodiment in the present invention is no need to inject an additional gas containing silicon element, and thus the cost is further saved. On the other hand, the required DC current of the plasma apparatus 300 of one embodiment in the present invention is reduced to lower than 50 amperes. Furthermore, no medium gas is needed to be injected to function as a source to produce plasma. Therefore, compare to the prior art, the plasma apparatus 300 of one embodiment in the present invention has simple and saving cost effect.

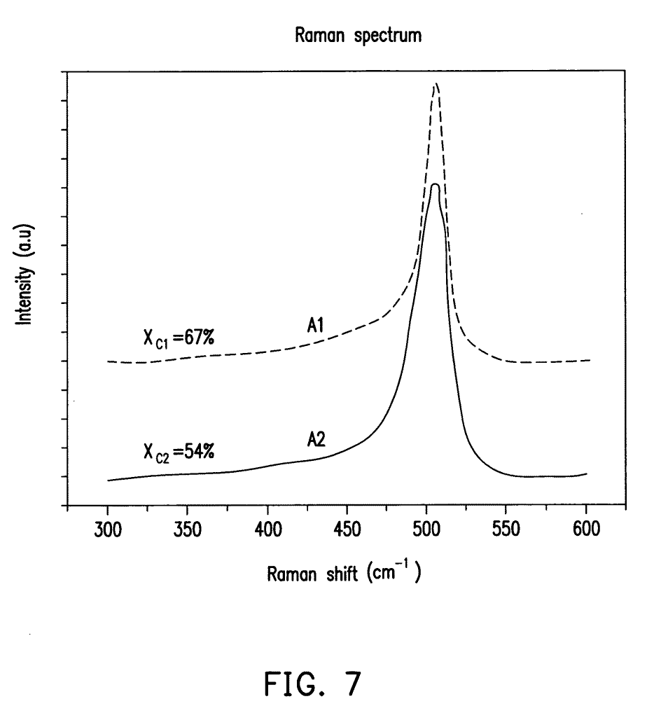

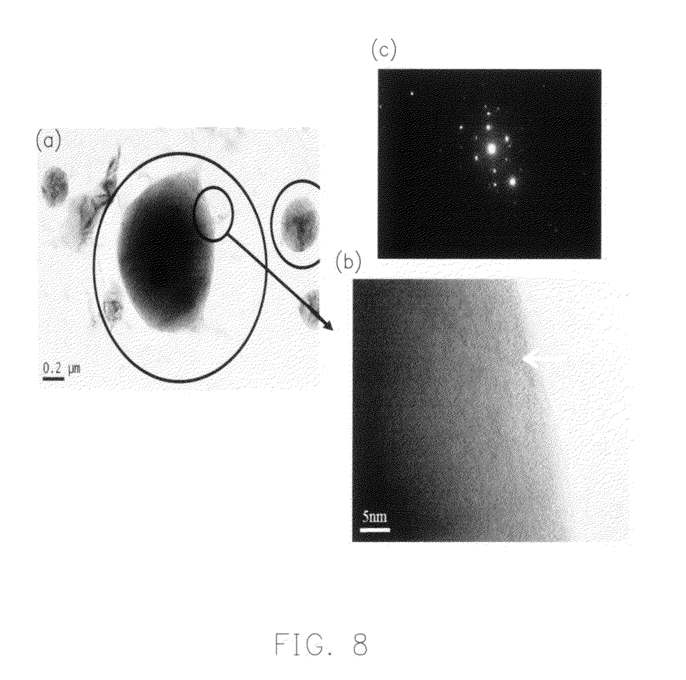

FIG. 7 is a Raman spectrum of a nano-crystalline thin film fabricating by a plasma apparatus of one embodiment of the present invention. Referring to FIG. 7, the crystalline volume ratio is defined as X_{c}, wherein the crystalline volume ratio X_{c} satisfies the following formula (1):

$${X}_{C} = \frac{{I}_{C}}{( {I}_{C} + {I}_{a} )} \qquad ( 1 )$$

In formula (1), I_{c} represents an integration of the peak of crystal phase, and Iₐ represents an integration of the peak of disordered silicon phase. As shown in FIG. 7, the crystalline volume ratio X_{c} are varied in different region of the thin film. For instance, the crystalline volume ratio X_{c} in the first region A1 of the nano-crystalline silicon thin film is substantial equal to 67%, and the crystalline volume ratio X_{c} in the first region A2 of the nano-crystalline silicon thin film is substantial equal to 54%.

In addition, FIG. 8 is schematic view of a structure analyzing of nano-crystalline silicon thin film fabricating by a plasma apparatus of one embodiment of the present invention, wherein drawings of (a), (b), and (c) in FIG. 8 are Transmission Electron Microscope of a nano-crystalline silicon thin film. Referring to the drawings of (a) and (b) illustrated in the FIG. 8, the structure of the nano-crystalline thin film mainly comprises a continuous phase of amorphous silicon layer, and a plurality of ball-shaped clusters with fully crystallized structure dispersed within the amorphous silicon layer. A ball-shaped clusters is buried in the matrix of amorphous silicon as represented in drawings of (a) and (b) in the FIG. 8. Moreover, referring to the drawings (c) illustrated in the FIG. 8, these ball-shaped clusters with fully crystallized structure are separated to each other and dispersed within the amorphous silicon thin film.

According to the above descriptions, the plasma apparatus and the method of fabricating a nano-crystalline thin film of the present invention have one or a part of or all of the following advantages:

1. A nano-crystalline silicon thin film with excellent quality can be fabricated by a simple process through utilizing an arc electrode set having crystallized silicon target.

2. In one embodiment, the cooling system is installed to the substrate holder to force the heated substrate during process to cool, so that nano-crystalline silicon thin films can be formed on the substrates which are vulnerable to heat.

3. Since the source of the silicon atoms and the silicon crystalline grains within the thin film are generated from the crystallized silicon targets, and thus the plasma apparatus in some embodiment of the present invention is no need to inject an additional gas containing silicon element, and thus the cost is further saved.

4. The required DC current of the plasma apparatus of the present invention is reduced to lower than 50 amperes, and thus the power can be further saved.

5. In some embodiment, the plasma apparatus is no need to inject a medium gas to function as a source to produce plasma, and thus the equipment and the process can be simplify and further saving cost.

Although the invention has been described with reference to the above embodiments, it is apparent to one of the ordinary skill in the art that modifications to the described embodiments may be made without departing from the spirit of the invention. Accordingly, the scope of the invention will be defined by the attached claims not by the above detailed descriptions.

What is claimed is:

1. A plasma apparatus, comprising:
a chamber;
an arc electrode set disposed in the chamber, wherein the arc electrode set comprises an anode and a cathode, an arc discharging space is formed between the anode and the cathode, an end of the cathode opposite to the anode and an end of the anode opposite to the cathode respectively has a crystallized silicon target, and a resistance of the crystallized silicon targets is smaller than 0.01 Ω·cm; and
a substrate holder disposed within the chamber, wherein the substrate holder has a carrier substrate, and the carrier surface faces to the arc discharging space.

2. The plasma apparatus as claimed in claim 1, wherein each of the crystallized silicon targets has a single crystal structure of silicon, the single crystal structure of silicon grains has dopants with a high dopant concentration, and the dopant concentration of the dopants within each of the single crystal structure of silicon grains is substantially from 10¹⁹ to 10²⁰ atom/cm².

3. The plasma apparatus as claimed in claim 1, wherein each of the crystallized silicon targets has a high dopant concentration, a material of the dopants is selected from III-group elements, and the crystallized silicon targets constitute P-type semiconductor targets.

4. The plasma apparatus as claimed in claim 1, wherein each of the crystallized silicon targets has a high dopant concentration, a material of the dopants is selected from V-group elements, and the crystallized silicon targets constitute N-type semiconductor targets.

5. The plasma apparatus as claimed in claim 1, wherein each of the crystallized silicon targets has a high dopant concentration, a material of the dopants includes III-group elements and V-group elements, and each of the crystallized silicon targets constitutes an intrinsic semiconductor target.

6. The plasma apparatus as claimed in claim 1, wherein a resistance of the crystallized silicon targets is greater than 0.005 Ω/cm.

7. The plasma apparatus as claimed in claim 1, further comprising a movable mechanism, wherein the movable mechanism is connected to the arc electrode set, so as to generate a relative displacement between the anode and the cathode by the movable mechanism.

8. The plasma apparatus as claimed in claim 1, further comprising a substrate, wherein the substrate is disposed on a carrier surface of the substrate holder, the substrate holder further comprises a cooling system, wherein the cooling system is buried inside the carrier surface, so as to force the substrate heated during process to cool.

9. The plasma apparatus as claimed in claim 8, wherein the cooling system comprises a cooling pipe and a coolant, the cooling pipe passes through a trench buried inside the substrate holder, and the coolant flows and circulates in the cooling pipe.

10. The plasma apparatus as claimed in claim 9, wherein the carrier surface is forced to cool to a temperature substantially smaller than 0° C. by the cooling system during the process.

11. The plasma apparatus of claim 9, wherein the coolant comprises water or liquid nitrogen.

12. The plasma apparatus as claimed in claim 8, wherein the substrate is a flexible substrate.

13. The plasma apparatus as claimed in claim 8, wherein a surface to be deposited of the substrate is a flat surface, a spherical surface or a mirror surface.

14. The plasma apparatus as claimed in claim 8, further comprising a continuous feeding system, wherein the continuous feeding system is connected to the substrate, and the substrate is carried to be disposed on the substrate holder through the continuous feeding system.

15. The plasma apparatus as claimed in claim 1, further comprising a gas pipe, wherein the gas pipe is disposed on a sidewall of the chamber, and a dopant gas passing through the gas pipe comprises diborane or phosphine.

16. A method of fabricating a nano-crystalline silicon thin film, suitable for fabricating by using the plasma apparatus as claimed in claim 1, the method of fabricating a nano-crystalline silicon thin film comprises:
providing a substrate on the carrier surface of the substrate holder;
adjusting a pressure of the gas within the chamber to an operation pressure;
inputting a voltage to form a voltage difference between the anode and the cathode;
shortening a distance between the anode and the cathode, so as to form a stable arc plasma between the anode and the cathode;
forming a plurality of silicon crystalline grains and silicon atoms through the crystallized silicon target of the anode and the crystallized silicon target of the cathode by the stable arc plasma; and
depositing the plurality of silicon crystalline grains and silicon atoms to the substrate to form a nano-crystalline silicon thin film.

17. The method of fabricating a nano-crystalline silicon thin film as claimed in claim 16, wherein the plurality of silicon crystalline grains and silicon atoms formed by the stable arc plasma are in a status of high temperature.

18. The method of fabricating a nano-crystalline silicon thin film as claimed in claim 17, wherein the substrate holder further comprises a cooling system, the cooling system is buried inside the carrier surface, and passing a coolant through the cooling system to force the heated substrate during process to cool before the step of forming the silicon crystalline grains and silicon atoms through the stable arc plasma, so that the high-temperature silicon crystalline grains and silicon atoms are quenched and deposited to the substrate.

19. The method of fabricating a nano-crystalline silicon thin film as claimed in claim 16, wherein the nano-crystalline silicon thin film comprises a continuous phase of amorphous silicon layer and a plurality of single crystal of silicon grains dispersed within the amorphous silicon layer.

20. The method of fabricating a nano-crystalline silicon thin film as claimed in claim 19, wherein a size of each of the single crystal of silicon grain substantially ranges from 100 nanometers to 5 micrometers.

21. The method of fabricating a nano-crystalline silicon thin film as claimed in claim 16, wherein the substrate is a flexible substrate, and the substrate is continuously fed, so that the nano-crystalline silicon thin film is continuously deposited on the continuous-fed substrate.
